(19) United States
(12) Patent Application Publication
(10) Pub. No.: US 2025/0212323 A1
(43) Pub. Date: Jun. 26, 2025

(54) PRINTED CIRCUIT BOARD AND SEMICONDUCTOR PACKAGE INCLUDING THE SAME

(71) Applicant: Samsung Electronics Co., Ltd., Suwon-si (KR)

(72) Inventors: Minjin Kim, Suwon-si (KR); Kwangho Park, Suwon-si (KR)

(21) Appl. No.: 18/985,423

(22) Filed: Dec. 18, 2024

(30) Foreign Application Priority Data
Dec. 21, 2023 (KR) 10-2023-0188650

(51) Int. Cl. H05K 1/02; H01L 23/538; H05K 1/11

(52) U.S. Cl. CPC H05K 1/0298; H01L 23/5385; H01L 23/5386; H05K 1/116

(57) ABSTRACT

A printed circuit board includes a base board and a wiring structure arranged on a top surface and a bottom surface of the base board and inside the base board. The wiring structure includes a plurality of common potential plates spaced apart from each other in a vertical direction, the plurality of common potential plates each having a cut area, a pair of differential signal lines spaced apart from a first common potential plate selected from among the plurality of common potential plates, the pair of differential signal lines each including an entry portion arranged in the cut area, and a first reinforcement structure extending from a second common potential plate selected from among the plurality of common potential plates and vertically overlapping a portion of the entry portion.

### CROSS-REFERENCE TO RELATED APPLICATION

This application is based on and claims priority under 35 U.S.C. § 119 to Korean Patent Application No. 10-2023-0188650, filed on Dec. 21, 2023, in the Korean Intellectual Property Office, the disclosure of which is incorporated by reference herein in its entirety.

### BACKGROUND

The inventive concept relates to a printed circuit board and a semiconductor package including the printed circuit board, and more particularly, to a printed circuit board capable of transmitting high-speed signals and a semiconductor package including the printed circuit board.

As electronic products are required to become more compact, multi-functional, and high-performance, semiconductor chips are becoming more highly integrated and faster. Accordingly, in order for semiconductor packages including semiconductor chips to respond to higher integration and higher speeds, printed circuit boards included in the semiconductor packages are also being developed to transmit high-speed signals.

### SUMMARY

The inventive concept provides a printed circuit board with improved reliability.

The inventive concept provides a semiconductor package including a printed circuit board with improved reliability.

According to an aspect of the inventive concept, there is provided a printed circuit board including a plurality of wiring layers spaced apart from each other in a vertical direction, the plurality of wiring layers each including a common potential plate having a cut area, and a plurality of conductive vias extending between the plurality of wiring layers, wherein the plurality of wiring layers include a first wiring layer spaced apart from the common potential plate, the first wiring layer including a pair of differential signal lines each including an entry portion extending into the cut area, a second wiring layer including a first reinforcement structure extending from the common potential plate and overlapping a portion of the entry portion in the vertical direction, and a pair of via pads spaced apart from the entry portion within the cut area, and a third wiring layer spaced apart from the first wiring layer in the vertical direction with the second wiring layer therebetween, the third wiring layer including a pair of lower pads in the cut area, and the plurality of conductive vias include a pair of line-side vias in contact with the pair of differential signal lines and the pair of via pads, and a pair of pad-side vias in contact with the pair of via pads and the pair of lower pads.

According to another aspect of the inventive concept, there is provided a printed circuit board including a base board and a wiring structure arranged on a top surface and a bottom surface of the base board and inside the base board, wherein the wiring structure includes a plurality of common potential plates spaced apart from each other in a vertical direction, the plurality of common potential plates each having a cut area, a pair of differential signal lines spaced apart from a first common potential plate selected from among the plurality of common potential plates, the pair of differential signal lines each including an entry portion arranged in the cut area, and a first reinforcement structure extending from a second common potential plate selected from among the plurality of common potential plates and overlapping a portion of the entry portion in the vertical direction.

According to another aspect of the inventive concept, there is provided a printed circuit board including a base board and a wiring structure arranged on a top surface and a bottom surface of the base board and inside the base board, wherein the wiring structure includes a plurality of common potential plates spaced apart from each other in a vertical direction, the plurality of common potential plates each having a cut area, a pair of differential signal lines spaced apart from a first common potential plate selected from among the plurality of common potential plates, the pair of differential signal lines each including an entry portion arranged in the cut area, a first reinforcement structure extending from a second common potential plate selected from among the plurality of common potential plates and overlapping a portion of the entry portion in the vertical direction, a second reinforcement structure selected from among the plurality of common potential plates, extending from a third common potential plate spaced apart from the second common potential plate in the vertical direction with the first common potential plate therebetween, and overlapping at least a portion of the entry portion in the vertical direction, a pair of lower pads arranged in the cut area on a bottom surface of the base board, a pair of via pads arranged inside the cut area and arranged at a vertical level lower than a vertical level of the first common potential plate, a pair of line-side vias extending between the pair of differential signal lines and the pair of via pads, and a pair of pad-side vias extending between the pair of lower pads and the pair of via pads.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package including a printed circuit board according to example embodiments;

FIG. 2A is a perspective view illustrating a printed circuit board according to example embodiments;

FIG. 2B is a plan view illustrating a printed circuit board according to example embodiments;

FIG. 3 is a cross-sectional view taken along line A1-A1′ of FIG. 2B;

FIG. 4 is an enlarged view of a region EX1 in FIG. 2B;

FIGS. 5A to 5D are plan views illustrating wiring layers at each vertical level of a printed circuit board according to example embodiments;

FIG. 6A is a plan view illustrating a printed circuit board according to example embodiments, and FIG. 6B is a cross-sectional view taken along line A2-A2′ of FIG. 6A;

FIG. 7 is a plan view illustrating a printed circuit board according to example embodiments;

FIG. 8A is a plan view illustrating a printed circuit board according to example embodiments, and FIG. 8B illustrates a portion corresponding to a cross-sectional view taken along line A4-A4′ of FIG. 8A; and

FIG. 9A is a plan view illustrating a printed circuit board according to example embodiments, and FIG. 9B is a cross-sectional view taken along lines A5-A5′ and A6-A6′ of FIG. 9A.

### DETAILED DESCRIPTION OF THE EMBODIMENTS

Embodiments will be described in detail with reference to the accompanying drawings. The same elements in the drawings are denoted by the same reference numerals, and redundant descriptions thereof are omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration. Herein, the X direction, the Y direction, and the Z direction may be perpendicular to each other.

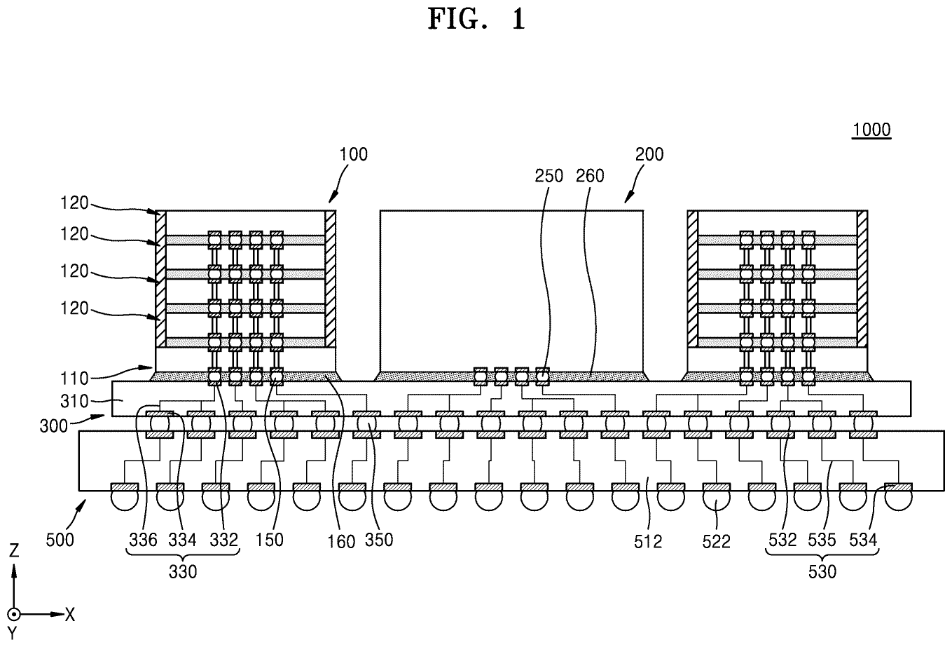

FIG. 1 is a cross-sectional view of a semiconductor package 1000 including a printed circuit board 500 according to example embodiments.

Referring to FIG. 1, the semiconductor package 1000 may include the printed circuit board 500, an interposer 300 attached to the printed circuit board 500, and a first chip structure 100 and a second chip structure 200 each attached to the interposer 300. In some embodiments, the first chip structure 100 and the second chip structure 200 may be spaced apart from each other in a horizontal direction (an X direction and/or a Y direction) and may each be attached to the interposer 300.

In some embodiments, the first chip structure 100 may include a first semiconductor chip 110 attached to the interposer 300 and at least one second semiconductor chip 120 attached to the first semiconductor chip 110. In the present specification, the first chip structure 100 may be referred to as a memory stack. In some embodiments, the second chip structure 200 may be a logic semiconductor chip including a semiconductor device such as a logic device.

Although FIG. 1 illustrates that the semiconductor package 1000 includes two first chip structures 100 and one second chip structure 200 attached to the interposer 300, the inventive concept is not limited thereto. For example, the semiconductor package 1000 may include one first chip structure or may include three or more first chip structures 100. Independently of the number of first chip structures 100, the semiconductor package 1000 may include two or more second chip structures 200.

According to embodiments, the printed circuit board 500 may include a base board 512, a top surface and a bottom surface of the base board 512 opposite one another, and a wiring structure 530 arranged inside the base board 512. The wiring structure 530 may include a plurality of upper pads 532, a plurality of lower pads 534, and a plurality of wiring paths 535.

According to embodiments, the upper pads 532 may be arranged on the top surface of the base board 512, and the lower pads 534 may be arranged on the bottom surface of the base board 512. The wiring paths 535 may electrically connect the upper pads 532 to the lower pads 534 through the base board 512. In some embodiments, the wiring paths 535 may be located inside the base board 512, but the inventive concept is not limited thereto. For example, some wiring paths 535 may extend from the upper pads 532 and/or the lower pads 534 and may be arranged on the top surface and/or the bottom surface of the base board 512, and other wiring paths 535 may be arranged inside the base board 512.

In some embodiments, the printed circuit board 500 may be a multi-layer printed circuit board.

In some embodiments, the base board 512 may include at least one material selected from among phenol resin, epoxy resin, and polyimide. For example, the base board 512 may include at least one material selected from among flame retardant 4 (FR4), tetrafunctional epoxy, polyphenylene ether, epoxy/polyphenylene oxide, bismaleimide triazine (BT), Thermount, cyanate ester, polyimide, and liquid crystal polymer. In some embodiments, the base board 512 may include, for example, polyester, polyester terephthalate (PET), fluorinated ethylene propylene (FEP), a resin-coated paper, liquid polyimide resin, or a polyethylene naphthalate (PEN) film.

In some embodiments, the upper pads 532 and the lower pads 534 may each include at least one selected among from copper, gold, nickel, stainless steel, and beryllium copper. In some embodiments, the wiring paths 535 may each include, for example, at least one selected among from electrolytically deposited (ED) copper, rolled-annealed (RA) copper foil, stainless steel foil, aluminum foil, ultra-thin copper foil, sputtered copper, copper alloy, nickel, stainless steel, and beryllium copper.

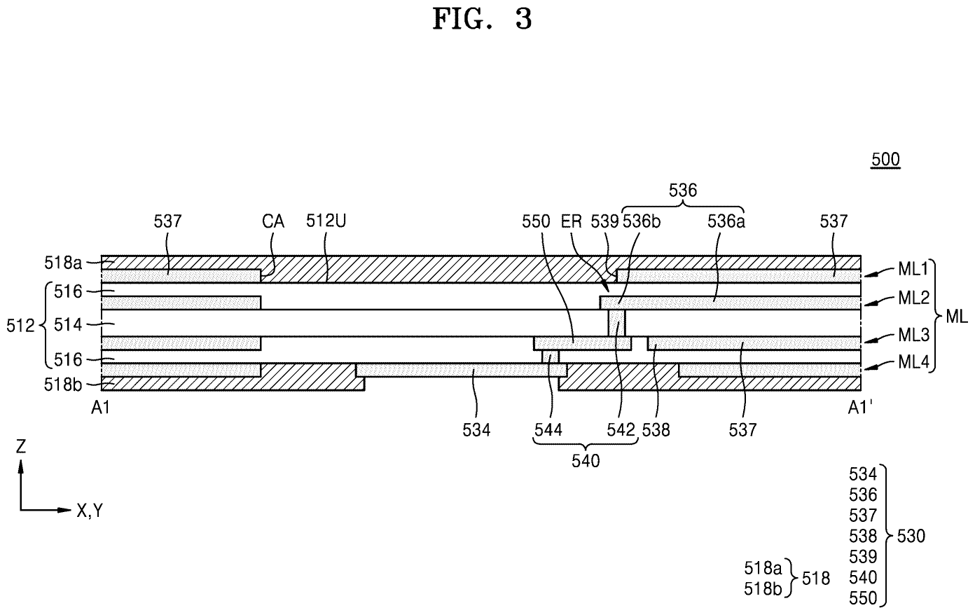

In some embodiments, the printed circuit board 500 may further include a solder resist layer (see, e.g., solder resist layer 518 of FIG. 3) that covers the top surface and the bottom surface of the base board 512 and exposes the upper pads 532 and the lower pads 534. The solder resist layer 518 may include a first solder resist layer (see, e.g., first solder resist layer 518a of FIG. 3) and a second solder resist layer (see, e.g., second solder resist layer 518b of FIG. 3). The first solder resist layer 518a may cover the top surface of the base board 512 and may expose at least some of the upper pads 532 without covering the upper pads 532. The second solder resist layer 518b may cover the bottom surface of the base board 512 and may expose at least some of the lower pads 534 without covering the lower pads 534.

According to embodiments, a plurality of interposer connection terminals 350 may be respectively connected to the upper pads 532, and a plurality of external connection terminals 522 may be respectively connected to the lower pads 534. The interposer connection terminals 350 may electrically connect the interposer 300 to the printed circuit board 500. The external connection terminals 522 respectively connected to the lower pads 534 may connect the semiconductor package 1000 to an external device. In some embodiments, the interposer connection terminals 350 and the external connection terminals 522 may each be a bump, a solder ball, or the like.

The interposer 300 may connect the printed circuit board 500 to the first chip structure 100 and the second chip structure 200. The interposer 300 may include an interposer substrate 310 and an interposer wiring structure 330. The interposer wiring structure 330 may include a plurality of interposer upper pads 332 arranged on a top surface of the interposer substrate 310, a plurality of interposer lower pads 334 arranged on a bottom surface of the interposer substrate 310, and a plurality of interposer wiring paths 336. In some embodiments, the interposer wiring paths 336 may respectively electrically connect the interposer upper pads 332 to the interposer lower pads 334 through the interposer substrate 310. The interposer connection terminals 350 may be respectively attached to the interposer lower pads 334. The interposer connection terminals 350 may be arranged between the upper pads 532 and the interposer lower pads 334 and electrically connect the interposer 300 to the printed circuit board 500.

In some embodiments, the interposer substrate 310 may include a semiconductor material, glass, ceramic, or plastic. For example, the interposer substrate 310 may include silicon (Si). In some embodiments, the interposer 300 may be a Si interposer in which the interposer substrate 310 is formed from a silicon semiconductor substrate.

A plurality of first chip connection terminals 150 and a plurality of second chip connection terminals 250 may be attached to the interposer upper pads 332. The first chip structure 100 may be connected to the interposer 300 through the first chip connection terminals 150, and the second chip structure 200 may be connected to the interposer through the second chip connection terminals 250. In some embodiments, the first chip connection terminals 150 and the second chip connection terminals 250 may each be a bump, a solder ball, or the like. A first underfill layer 160 surrounding the first chip connection terminals 150 may be arranged between the interposer 300 and the first chip structure 100, and a second underfill layer 260 surrounding the second chip connection terminals 250 may be arranged between the interposer 300 and the second chip structure 200. The first underfill layer 160 and the second underfill layer 260 may include, for example, epoxy resin formed by a capillary under-fill method. In some embodiments, the first underfill layer 160 and the second underfill layer 260 may each be a non-conductive film (NCF).

Although FIG. 1 illustrates that the first chip structure 100 includes one first semiconductor chip 110 and four second semiconductor chips 120, the inventive concept is not limited thereto. For example, the first chip structure 100 may include one, two, three, or five or more second semiconductor chips 120. In some embodiments, the first chip structure 100 may include the second semiconductor chips 120 in multiples of 4. The second semiconductor chips 120 may be sequentially stacked on the first semiconductor chip 110 in a vertical direction.

In some embodiments, the first semiconductor chip 110 and the second semiconductor chips 120 may each be a dynamic random access memory (DRAM), a static random access memory (SRAM), a flash memory, an electrically erasable and programmable read-only memory (EEPROM), a phase-change random access memory (PRAM), a magnetic random access memory (MRAM), or a resistive random access memory (RRAM).

In some embodiments, the first semiconductor chip 110 may not include memory cells. The first semiconductor chip 110 may include a serial-parallel conversion circuit, a test logic circuit (e.g., a design for test (DFT), a Joint Test Action Group (JTAG), a memory built-in self-test (MBIST), etc.), and a signal interface circuit such as PHY. In some embodiments, the second semiconductor chips 120 may include memory cells. For example, the first semiconductor chip 110 may be a buffer chip for controlling the second semiconductor chips 120.

In some embodiments, the first semiconductor chip 110 may be a buffer chip for controlling a high bandwidth memory (HBM) DRAM, and the second semiconductor chips 120 may be memory cell chips having HBM DRAM cells controlled by the first semiconductor chip 110. In the present specification, the first semiconductor chip 110 may be referred to as a buffer chip or a master chip, and the second semiconductor chip 120 may be referred to as a slave chip or a memory cell chip. In the present specification, the first chip structure 100 including the first semiconductor chip 110 and the second semiconductor chips 120 sequentially stacked on the first semiconductor chip 110 may be referred to as an HBM DRAM device.

In some embodiments, the second chip structure 200 may be, for example, a central processing unit (CPU) chip, a graphic processing unit (GPU) chip, an application processor (AP) chip, an application specific integrated circuit (ASIC), or other processing chips.

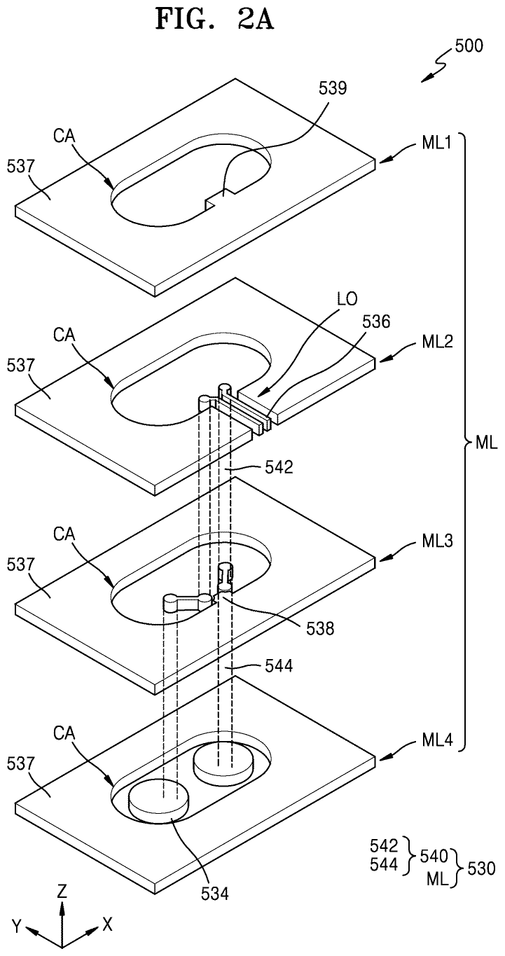

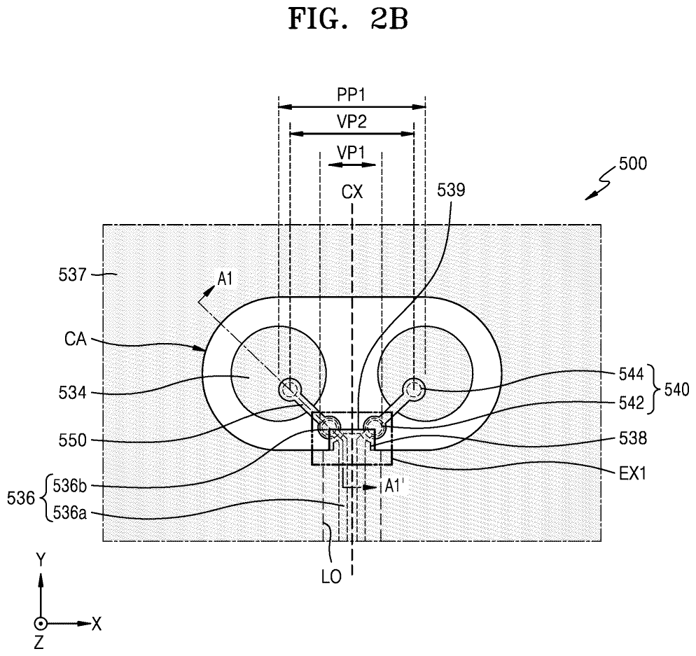

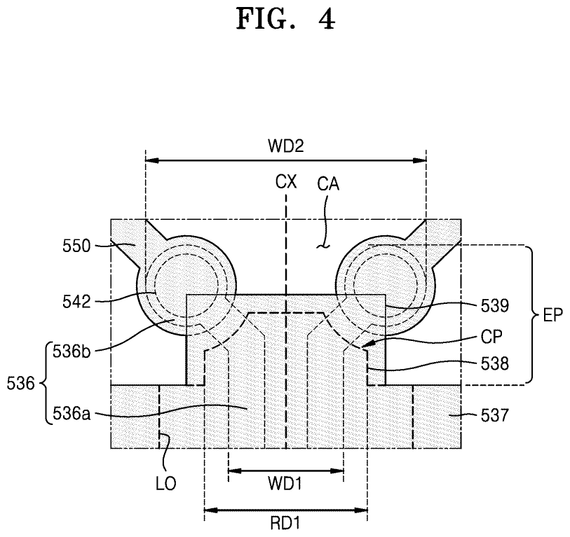

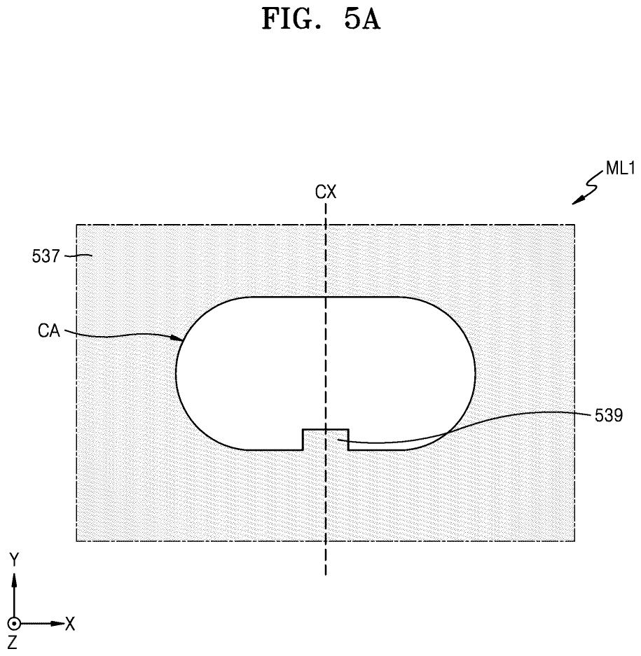

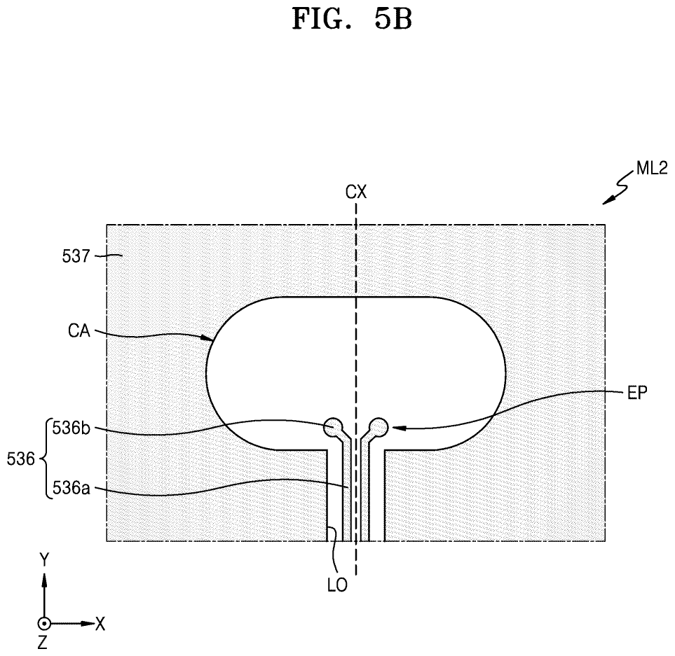

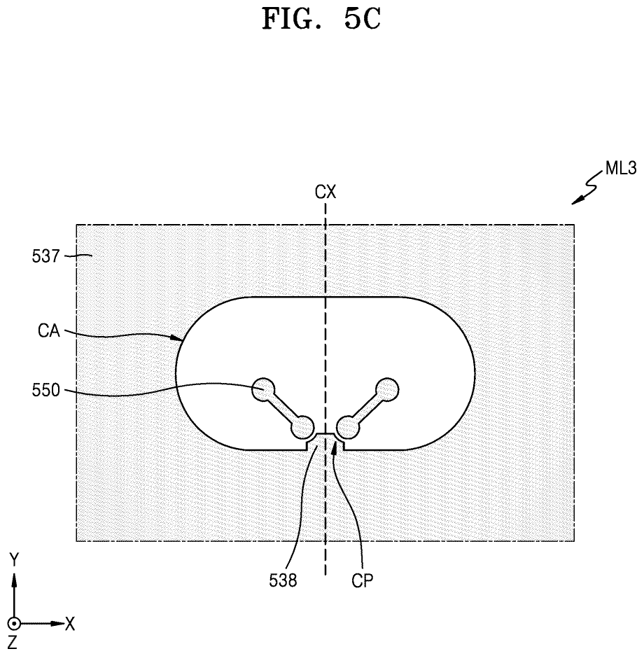

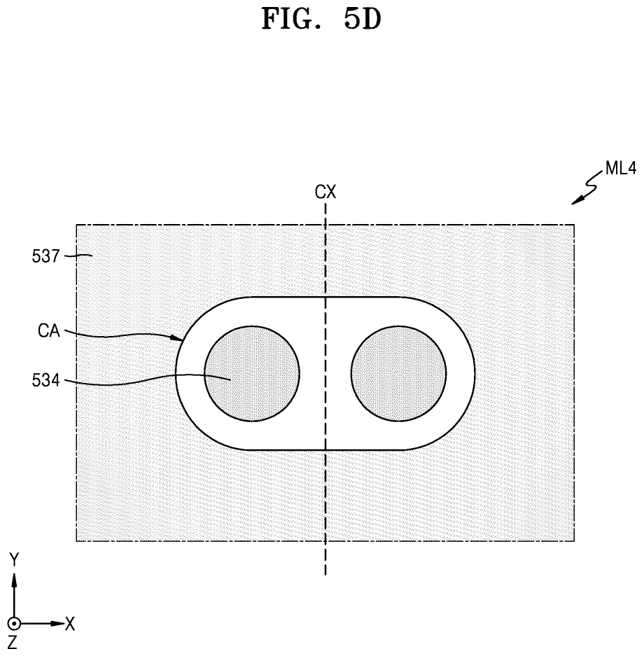

FIG. 2A is a perspective view illustrating the printed circuit board 500 according to example embodiments. FIG. 2A illustrates a portion of the printed circuit board 500 described with reference to FIG. 1. FIG. 2B is a plan view illustrating the printed circuit board 500 according to example embodiments. FIG. 3 is a cross-sectional view taken along line A1-A1′ of FIG. 2B, and FIG. 4 is an enlarged view of a region EX1 in FIG. 2B. FIGS. 5A to 5D are plan views illustrating wiring layers ML at each vertical level of the printed circuit board 500 according to example embodiments. Specifically, FIG. 5A illustrates a first wiring layer ML1, FIG. 5B illustrates a second wiring layer ML2, FIG. 5C illustrates a third wiring layer ML3, and FIG. 5D illustrates a fourth wiring layer ML4.

Referring to FIGS. 2A to 5D, the printed circuit board 500 may include a base board 512 and a wiring structure 530. The wiring structure 530 may be arranged on a top surface 512U and a lower surface of the base board 512 and may be arranged inside the base board 512.

According to embodiments, the base board 512 may include a plurality of board layers stacked in a vertical direction (a Z direction). In some embodiments, the base board 512 may include a core board layer 514 and a sub-board layer 516 arranged on each of a top surface and a bottom surface of the core board layer 514. Although FIG. 3 illustrates that the thickness of the core board layer 514 in the vertical direction (the Z direction) is equal to the thicknesses of the sub-board layers 516 in the vertical direction (the Z direction), the inventive concept is not limited thereto. In some embodiments, the thickness of the core board layer 514 in the vertical direction (the Z direction) may be greater than the thicknesses of the sub-board layers 516 in the vertical direction (the Z direction). In some embodiments, the core board layer 514 and the sub-board layers 516 may each include at least one material selected among from phenol resin, epoxy resin, and polyimide.

According to embodiments, the wiring structure 530 may include a plurality of wiring layers ML apart from each other in the vertical direction (the Z direction) and a plurality of conductive vias 540 extending between the wiring layers ML in the vertical direction (the Z direction). According to embodiments, the wiring layers ML may be arranged at different vertical levels and may extend in the horizontal direction (the X direction and/or the Y direction). In the present specification, the “vertical level” refers to the distance from the top surface 512U of the base board 512 in the vertical direction (the −Z direction or the +Z direction). According to embodiments, the conductive vias 540 may penetrate through at least a portion of the base board 512 and may connect two wiring layers ML selected from among the wiring layers ML.

According to embodiments, the wiring structure 530 may include a plurality of upper pads 532, a plurality of lower pads 534, a common potential plate 537, a plurality of differential signal lines 536, a plurality of via pads 550, a first reinforcement structure 538, and a second reinforcement structure 539. The upper pads 532, the lower pads 534, the common potential plate 537, the differential signal lines 536, the via pads 550, the first reinforcement structure 538, and the second reinforcement structure 539 may constitute the wiring layers ML. For example, the upper pads 532, the lower pads 534, the conductive vias 540, the differential signal lines 536, and the via pads 550 may constitute the wiring path 535 of the printed circuit board 500 in the semiconductor package 1000 described with reference to FIG. 1. For example, FIGS. 2A to 5D illustrate only one end portion of a pair of differential signal lines 536, but the omitted other end portion of the pair of differential signal lines 536 may be connected to some upper pads (see, e.g., upper pads 532 of FIG. 1) through some conductive vias 540.

Although FIG. 3 illustrates that the wiring structure 530 includes four wiring layers ML1, ML2, ML3, and ML4, the inventive concept is not limited thereto. For example, the wiring structure may include five or more wiring layers ML. In some embodiments, the first wiring layer ML1 may be arranged on the top surface of the first sub-board layer 516 that is arranged on the top surface of the core board layer 514. The second wiring layer ML2 may be arranged on the top surface of the core board layer 514 and covered with the first sub-board layer 516. In some embodiments, the fourth wiring layer ML4 may be arranged on the bottom surface of the second sub-board layer 516 that is arranged on the lower surface of the core board layer 514. The third wiring layer ML3 may be arranged on the bottom surface of the core board layer 514 and covered with the second sub-board layer 516. For example, the first wiring layer ML1 may be spaced apart from the second wiring layer ML2 in the vertical direction (the Z direction) with the first sub-board layer 516 therebetween. The second wiring layer ML2 may be spaced apart from the third wiring layer ML3 in the vertical direction (the Z direction) with the core board layer 514 therebetween. The third wiring layer ML3 may be spaced apart from the fourth wiring layer ML4 in the vertical direction (the Z direction) with the second sub-board layer 516 therebetween.

According to embodiments, the wiring layer ML arranged at the highest vertical level from among the wiring layers ML, for example, the first wiring layer ML1, may include a plurality of upper pads (see, e.g., upper pads 532 of FIG. 1). The wiring layer ML arranged at the lowest vertical level from among the wiring layers ML, for example, the fourth wiring layer ML4, may include a plurality of lower pads 534. In some embodiments, the first wiring layer ML1 may be arranged on the top surface 512U of the base board 512. The first wiring layer ML1 may be covered with the first solder resist layer 518a that covers the top surface 512U of the base board 512, and the upper pads (see, e.g., upper pads 532 of FIG. 1) of the first wiring layer ML1 may be exposed without being covered with the first solder resist layer 518a. In some embodiments, the fourth wiring layer ML4 may be arranged on the bottom surface of the base board 512. The fourth wiring layer ML4 may be covered with the second solder resist layer 518b that covers the bottom surface of the base board 512, and the lower pads 534 of the fourth wiring layer ML4 may be exposed without being covered with the second solder resist layer 518b. In the present specification, the first wiring layer ML1 may be referred to as an uppermost wiring layer, and the fourth wiring layer ML4 may be referred to as a lowermost wiring layer.

According to embodiments, the wiring layers ML may each include a common potential plate 537 having a cut area CA. In some embodiments, the cut areas CA of the wiring layers ML may overlap each other while being aligned with each other in the vertical direction (the Z direction). The base board 512 or the solder resist layer 518 may be arranged in the cut area CA of each of the wiring layers ML. In some embodiments, the common potential plate 537 may be a power plate to which power is provided or a ground plate to which ground is provided.

Referring to FIGS. 2A, 2B, and 5D, a pair of lower pads 534 selected from among the lower pads 534 may be spaced apart from the common potential plate 537 within the cut area CA. According to embodiments, the pair of lower pads 534 may be spaced apart from each other in the first horizontal direction (the X direction). In some embodiments, the pair of lower pads 534 may be symmetrically arranged with respect to a virtual center line CX extending in the second horizontal direction (the Y direction) perpendicular to the first horizontal direction (the X direction). In some embodiments, the second solder resist layer 518b may be arranged between the pair of lower pads 534 and between the common potential plate 537 and the pair of lower pads 534.

In some embodiments, the pair of lower pads 534 may each have a circular planar shape, but the inventive concept is not limited to the above-described example. In some embodiments, the pair of lower pads 534 may have a diameter of about 250 μm to about 700 μm.

In some embodiments, the pair of lower pads 534 may have a first pad pitch PP1 and may be spaced apart from each other. In the present specification, the “pad pitch” refers to the distance in the horizontal direction (the X direction and/or the Y direction) between the centers of the pair of lower pads 534. In some embodiments, the first pad pitch PP1 may be about 300 μm to about 1,200 μm. In some embodiments, the pair of lower pads 534 may be spaced apart from each other by a first distance in the first horizontal direction (the X direction). For example, the first distance may be about 150 μm to about 350 μm.

According to embodiments, the differential signal lines 536 may form pairs and extend in the horizontal direction (the X direction and/or the Y direction). Referring to FIGS. 2A, 2B, 4, and 5B, the differential signal lines 536 may extend lengthwise in the horizontal direction (the X direction and/or the Y direction) within a line opening area LO and may be spaced apart from the common potential plate 537 with the base board 512 or the solder resist layer 518 therebetween. Although FIGS. 2A, 2B, 4, and 5B illustrate that only the second wiring layer ML2 from among the wiring layers ML includes the differential signal lines 536, the inventive concept is not limited thereto.

According to embodiments, the differential signal lines 536 may include a signal line 536a extending lengthwise in the horizontal direction (the X direction and/or the Y direction) and a signal pad 536b connected to one selected from among the conductive vias 540 at one end portion of the signal line 536a. For example, the signal line 536a may extend within the line opening area LO.

According to embodiments, the line opening area LO may be connected to the cut area CA, and one end portion of the pair of differential signal lines 536 may extend into the cut area CA. The pair of differential signal lines 536 may be coupled to each other while being spaced apart from each other.

According to embodiments, the pair of differential signal lines 536 may be spaced apart from the pair of lower pads 534 in a plan view. For example, the pair of differential signal lines 536 may include an entry portion EP arranged within the cut area CA. The entry portion EP may include a portion of the pair of signal lines 536a and the pair of signal pads 536b. The entry portion EP may not vertically overlap the pair of lower pads 534.

In some embodiments, in the cut area CA, the pair of differential signal lines 536 may be symmetrically arranged with respect to the center line CX. For example, in the cut area CA, the pair of differential signal lines 536 may be spaced apart from each other in the first horizontal direction (the X direction) with the center line CX therebetween. In example embodiments, the pair of differential signal lines 536 may have mirror symmetry to each another.

In some embodiments, the width of the signal line 536a may be about 5 μm to about 30 μm. In some embodiments, the signal lines 536a of the pair of differential signal lines 536 may be spaced apart from each other by about 5 μm to about 30 μm. In some embodiments, the signal pad 536b may have a circular planar shape, but the inventive concept is not limited thereto. In some embodiments, the diameter of the signal pad 536b may be about 60 μm to about 200 μm, but the inventive concept is not limited to the above-described range.

According to embodiments, the third wiring layer ML3 between the second wiring layer ML2 including the pair of differential signal lines 536 and the fourth wiring layer ML4 including the pair of lower pads 534 may include the pair of via pads 550 selected from among the via pads 550. The pair of via pads 550 may be spaced apart from the common potential plate 537 in the cut area CA. According to embodiments, the via pads 550 may be spaced apart from each other in the first horizontal direction (the X direction) within the cut area CA. In a plan view, the via pads 550 may be symmetrically arranged with respect to the center line CX. In example embodiments, the via pads 550 may have mirror symmetry to each another.

According to embodiments, the pair of via pads 550 may include a first portion vertically overlapping one selected from among the pair of differential signal lines 536, and a second portion vertically overlapping one selected from among the pair of lower pads 534. According to embodiments, the conductive vias 540 may include a pair of line-side vias 542 extending between the pair of differential signal lines 536 and the pair of via pads 550, and a pair of pad-side vias 544 extending between the pair of via pads 550 and the pair of lower pads 534. One end portion of the pair of line-side vias 542 in the vertical direction (the Z direction) may be in contact with the signal pad 536b of the pair of differential signal lines 536, and the other end portion of the pair of line-side vias 542 may be in contact with the first portion of the pair of via pads 550. One end portion of the pair of pad-side vias 544 in the vertical direction (the Z direction) may be in contact with the pair of lower pads 534, and the other end portion of the pair of pad-side vias 544 may be in contact with the second portion of the pair of via pads 550.

The first portion of each of the pair of via pads 550 may be in contact with the corresponding line-side via 542 from among the pair of line-side vias 542 and may be connected to the corresponding differential signal line 536 from among the pair of differential signal lines 536. The second portion of each of the pair of via pads 550 may be in contact with the corresponding pad-side via 544 from among the pair of pad-side vias 544 and may be connected to the corresponding lower pad 534 from among the pair of lower pads 534. For example, the pair of differential signal lines 536 may be connected to the pair of lower pads 534 through the pair of line-side vias 542, the pair of via pads 550, and the pair of pad-side vias 544.

In some embodiments, in a plan view, the pair of line-side vias 542 may be arranged closer to the pair of differential signal lines 536 than the pair of pad-side vias 544, and the pair of pad-side vias 544 may be arranged closer to the pair of lower pads 534 than the pair of line-side vias 542.

In some embodiments, the pair of line-side vias 542 and the pair of pad-side vias 544 may not overlap each other in the vertical direction (the Z direction). For example, in a plan view, the pair of line-side vias 542 and the pair of pad-side vias 544 may be in contact with each other at a boundary or may be spaced apart from each other in a horizontal direction (the X direction and/or the Y direction).

In some embodiments, the pair of line-side vias 542 may be spaced apart from each other in the first horizontal direction (the X direction), and in a plan view, may be symmetrically arranged with respect to the center line CX. In some embodiments, the pair of pad-side vias 544 may be spaced apart from each other in the first horizontal direction (the X direction), and in a plan view, may be symmetrically arranged with respect to the center line CX.

In some embodiments, the separation distance between the pair of vias 542 and 544 may increase as the distance from the pair of differential signal lines 536 increases. In some embodiments, the pair of line-side vias 542 may have a first via pitch VP1 and may be spaced apart from each other, and the pair of pad-side vias 544 may have a second via pitch VP2 and may be spaced apart from each other. In some embodiments, the second via pitch VP2 may be greater than the first via pitch VP1. In some embodiments, the first pad pitch PP1 may be greater than the second via pitch VP2, but the inventive concept is not limited thereto. For example, the second via pitch VP2 may be equal to or less than the first pad pitch PP1.

In some embodiments, in a plan view, the pair of line-side vias 542 and the pair of pad-side vias 544 may be arranged in a V-shape. In some embodiments, the pair of line-side vias 542, the pair of pad-side vias 544, and the pair of lower pads 534 may be arranged so that the pitch thereof increases as the distance from the pair of differential signal lines 536 increases, and thus, may have a V-shape in a plan view. In some embodiments, the first portion of each of the pair of via pads 550 may be arranged closer to the center line CX than the second portion. For example, the distance between the pair of via pads 550 in the first horizontal direction (the X direction) may increase as the distance from the entry portion EP increases. For example, in a plan view, the pair of via pads 550 may have a V-shape with a sharp tip removed.

In some embodiments, in a plan view, the first line-side via 542 from among the pair of line-side vias 542, the first pad-side via 544 from among the pair of pad-side vias 544, and the first lower pad 534 from among the pair of lower pads 534 may be arranged on one side with respect to the center line CX. In some embodiments, in a plan view, the second line-side via 542 from among the pair of line-side vias 542, the second pad-side via 544 from among the pair of pad-side vias 544, and the second lower pad 534 from among the pair of lower pads 534 may be arranged on the other side opposite to the one side with respect to the center line CX. In some embodiments, the first line-side via 542, the first pad-side via 544, and the first lower pad 534 may be arranged symmetrically with the second line-side via 542, the second pad-side via 544, and the second lower pad 534 with respect to the center line CX.

In some embodiments, the center of the first line-side via 542, the center of the first pad-side via 544, and the center of the first lower pad 534 may be arranged on a first straight line, and the center of the second line-side via 542, the center of the second pad-side via 544, and the center of the second lower pad 534 may be arranged on a second straight line. As the first straight line and the second straight line become farther away from the pair of differential signal lines 536, the distance from the center line CX in the first horizontal direction (the X direction) may increase. The first straight line and the second straight line may extend symmetrically with respect to the center line CX. In some embodiments, the pair of via pads 550 may respectively extend along the first straight line and the second straight line.

Referring to FIGS. 4 and 5C, the third wiring layer ML3 may include a first reinforcement structure 538 that protrudes from the common potential plate 537 toward the cut area CA and partially vertically overlaps the entry portion EP of the pair of differential signal lines 536. According to embodiments, the first reinforcement structure 538 may be spaced apart from the pair of via pads 550. For example, a portion of the base board 512 may be arranged between the pair of via pads 550 and the first reinforcement structure 538. In some embodiments, the first reinforcement structure 538 may be spaced apart from the entry portion EP in the vertical direction (the Z direction) with a portion of the base board 512 therebetween and may partially cover the bottom surface of the entry portion EP.

In some embodiments, the first reinforcement structure 538 may partially cover the pair of signal lines 536a of the entry portion EP and may extend in the extension direction of the entry portion EP, for example, in the second horizontal direction (the Y direction). In some embodiments, the first reinforcement structure 538 may have a first horizontal width RD1 in the first horizontal direction (the X direction), which is sufficient to cover the pair of signal lines 536a of the entry portion EP. For example, the first horizontal width RD1 may be greater than a first horizontal length WD1, which is the sum of the width of each of the pair of signal lines 536a and the distance between the pair of differential signal lines 536. In some embodiments, as illustrated in FIGS. 2B and 3, the pair of signal lines 536a of the entry portion EP may each include a portion bent in a direction away from each other. In this case, the first reinforcement structure 538 may include a portion that vertically overlaps the bent portion. In some embodiments, the pair of signal lines 536a of the entry portion EP may not include the bent portion, and the pair of signal lines 536a of the entry portion EP may be spaced apart from each other by the same distance as the separation distance between the pair of differential signal lines 536. In some embodiments, the first horizontal width RD1 may be equal to or less than a second horizontal length WD2, which is the sum of the diameter of each of the pair of signal pads 536b and the distance between the pair of signal pads 536b. In some embodiments, the first horizontal width RD1 may be greater than the second horizontal length WD2.

In some embodiments, a portion of a sidewall of the first reinforcement structure 538 may face each of the pair of via pads 550 with the base board 512 therebetween. In some embodiments, the first reinforcement structure 538 may include a chamfered portion CP that is recessed along the sidewall of each of the pair of via pads 550. In some embodiments, in a plan view, the chamfered portion CP of the first reinforcement structure 548 may have a profile corresponding to a sidewall of each of an adjacent pair of via pads 550. In some embodiments, the first reinforcement structure 528 may have a planar shape that is symmetrical with respect to the center line CX.

According to embodiments, the first wiring layer ML1 may include a second reinforcement structure 539 that protrudes from the common potential plate 537 toward the cut area CA on the pair of differential signal lines 536 and at least partially vertically overlaps the entry portion EP of the pair of differential signal lines 536 in the vertical direction (the Z direction). According to embodiments, the first reinforcement structure 538 may be arranged on one side of the entry portion EP in the vertical direction (the Z direction), and the second reinforcement structure 539 may be arranged on the other side of the entry portion EP in the vertical direction (the Z direction). For example, the entry portion EP may have a sandwiched structure between the first reinforcement structure 538 and the second reinforcement structure 539. For example, the second reinforcement structure 539 may be spaced apart from the first reinforcement structure 538 in the vertical direction (the Z direction) with the entry portion EP therebetween. In the present specification, the first reinforcement structure 538 may be referred to as a lower reinforcement structure, and the second reinforcement structure 539 may be referred to as an upper reinforcement structure.

In some embodiments, the second reinforcement structure 539 may be spaced apart from the entry portion EP in the vertical direction (the Z direction) with a portion of the base board 512 therebetween and may at least partially cover the top surface of the entry portion EP. In some embodiments, the second reinforcement structure 539 may cover the top surfaces of the pair of signal lines 536a of the entry portion EP and may extend in the extension direction of the entry portion EP, for example, in the second horizontal direction (the Y direction). For example, the pair of signal lines 536a of the entry portion EP may vertically overlap the second reinforcement structure 539. In some embodiments, the second reinforcement structure 539 may at least partially vertically overlap the pair of signal pads 536b of the entry portion EP. In some embodiments, the second reinforcement structure 539 may vertically overlap at least a portion of the pair of line-side vias 542 and a portion of the pair of via pads 550.

In some embodiments, the second reinforcement structure 539 may have a second horizontal width in the first horizontal direction (the X direction), which is sufficient to cover the pair of signal lines 536a of the entry portion EP. In some embodiments, the second horizontal width may be substantially equal to the first horizontal width RD1 of the first reinforcement structure 538. In some embodiments, the second horizontal width may be substantially different from the first horizontal width RD1. In some embodiments, the width of the second reinforcement structure 539 in the second horizontal direction (the Y direction) may be less than the length of the entry portion EP in the second horizontal direction (the Y direction), but the inventive concept is not limited thereto. For example, the width of the second reinforcement structure 539 in the second horizontal direction (the Y direction) may be substantially equal to the length of the entry portion EP in the second horizontal direction (the Y direction) or may be greater than the length of the entry portion EP in the second horizontal direction (the Y direction).

In some embodiments, the first reinforcement structure 538 and the second reinforcement structure 539 may each be formed integrally with the common potential plate 537. For example, the same voltage as that of the common potential plate 537 connected to the first reinforcement structure 538 and the second reinforcement structure 539 may be applied to each of the first reinforcement structure 538 and the second reinforcement structure 539.

The printed circuit board 500 according to embodiments may include the first reinforcement structure 538 and the second reinforcement structure 539 that vertically overlap the entry portion EP of the pair of differential signal lines 536. The first reinforcement structure 538 and the second reinforcement structure 539 may be included respectively in the third wiring layer ML3 and the first wiring layer ML1 adjacent to the second wiring layer ML2, each including the pair of differential signal lines 536. Accordingly, the first reinforcement structure 538 and the second reinforcement structure 539 may each form a capacitance with the entry portion EP, and thus, the impedance deviation of the wiring path connecting the pair of differential signal lines 536 to the pair of lower pads 534 may be reduced. In a plan view, the differential signal line 536 according to embodiments may be spaced apart from the pair of lower pads 534 and may be connected to the pair of lower pads 534 through the pair of line-side vias 542, the pair of pad-side vias 544, and the pair of via pads 550. The first via pitch VP1 of the pair of line-side vias 542 may be less than the second via pitch VP2 of the pair of pad-side vias 544. In a plan view, the pair of line-side vias 542 and the pair of pad-side vias 544 may be arranged in a V-shape. Accordingly, the impedance deviation along the wiring path may be reduced, and thus, the electrical reliability of the printed circuit board 500 may be improved.

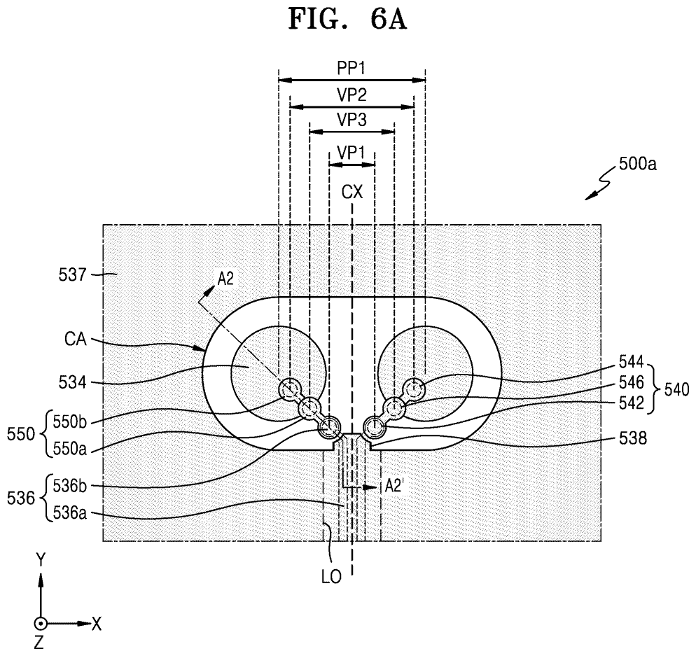

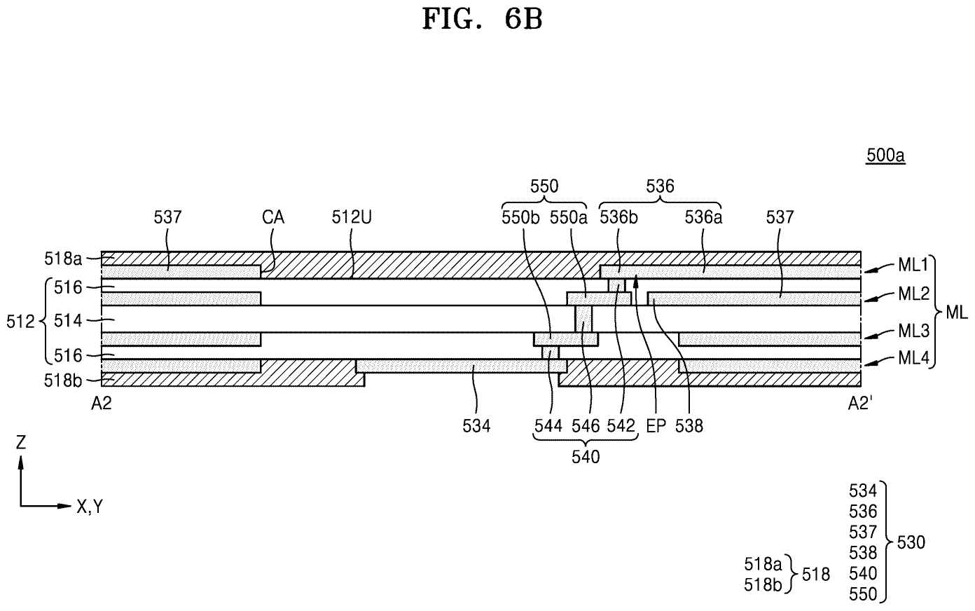

FIG. 6A is a plan view illustrating a printed circuit board 500a according to some example embodiments, and FIG. 6B is a cross-sectional view taken along line A2-A2′ of FIG. 6A. In FIGS. 6A and 6B, the same reference numerals as those in FIGS. 2A to 5D denote the same members, and descriptions thereof are not repeated.

Referring to FIGS. 6A and 6B, the printed circuit board 500a may include three pairs of conductive vias 542, 544, and 546 apart from each other in the vertical direction (the Z direction) in a cut area CA. Unlike the printed circuit board 500 described with reference to FIGS. 2A to 5D, the printed circuit board 500a may include a pair of differential signal lines 536 arranged on an uppermost wiring layer ML1. In the printed circuit board 500a, the second reinforcement structure 539 covering the top surface of the entry portion EP, which has been described with reference to FIGS. 2A to 5D, may be omitted. In some embodiments, the pair of differential signal lines 536 may be covered with a first solder resist layer 518a.

According to embodiments, the printed circuit board 500 may include three pairs of conductive vias 542, 544, and 546 and two pairs of via pads 550a and 550b, which are disposed between a first wiring layer ML1 including the pair of differential signal lines 536 and a fourth wiring layer ML4 including a pair of lower pads 534. The pair of upper via pads 550a may be included in the second wiring layer ML2 and may be spaced apart from the common potential plate 537 and the first reinforcement structure 538 within the corresponding cut area CA. The pair of lower via pads 550b may be included in the third wiring layer ML3 and may be spaced apart from the common potential plate 537 within the corresponding cut area CA.

According to embodiments, the pair of line-side vias 542 may extend between the first wiring layer ML1 and the second wiring layer ML2. The pair of line-side vias 542 may be in contact with the entry portion EP at one end in the vertical direction (the Z direction) and may be in contact with the pair of upper via pads 550a at the other end. The pair of pad-side vias 544 may extend between the third wiring layer ML3 and the fourth wiring layer ML4. The pair of pad-side vias 544 may be in contact with the pair of lower via pads 550b at one end in the vertical direction (the Z direction) and may be in contact with the pair of lower pads 534 at the other end. The pair of intermediate vias 546 may extend between the second wiring layer ML2 and the third wiring layer ML3. The pair of conductive vias 546 may be in contact with the pair of upper via pads 550a at one end in the vertical direction (the Z direction) and may be in contact with the pair of lower via pads 550b at the other end in the vertical direction (the Z direction). For example, the three pairs of conductive vias 542, 544, and 546 and the two pairs of via pads 550a and 550b may constitute a wiring path (see, e.g., wiring path 535 of FIG. 1).

In some embodiments, the three pairs of conductive vias 542, 544, and 546 may not overlap each other in the vertical direction (the Z direction). In some embodiments, in a plan view, the pair of intermediate vias 546 may be arranged between the pair of line-side vias 542 and the pair of pad-side vias 544. In some embodiments, the pair of intermediate vias 546 may be spaced apart from each other in the first horizontal direction (the X direction) and may be symmetrically arranged with respect to the center line CX.

In some embodiments, the distance from the center line CX of each of the three pairs of conductive vias 542, 544, and 546 may increase as the distance from the entry portion EP increases. In some embodiments, the pair of intermediate vias 546 may have a third via pitch VP3. The third via pitch VP3 may be greater than the first via pitch VP1 and less than the second via pitch VP2.

In some embodiments, the three pairs of conductive vias 542, 544, and 546 may be symmetrically arranged with respect to the center line CX. In some embodiments, in a plan view, the three pairs of conductive vias 542, 544, and 546 may be arranged in a V-shape.

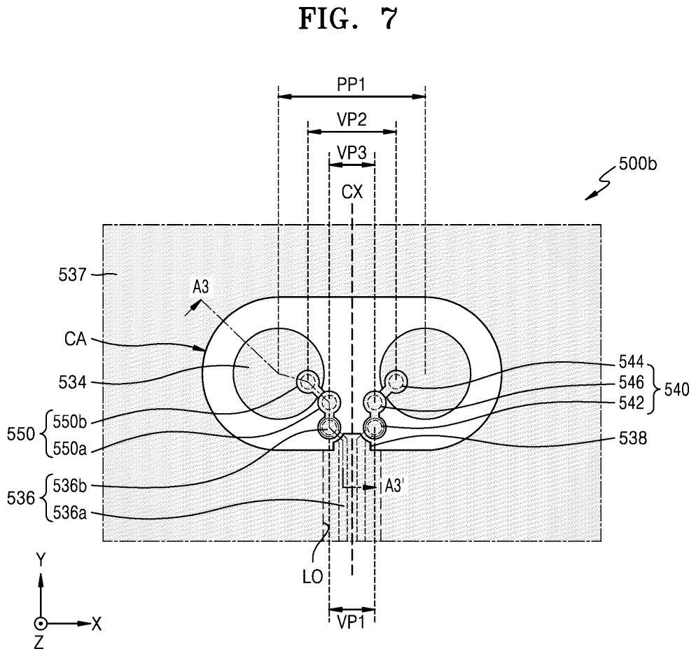

FIG. 7 is a plan view illustrating a printed circuit board 500b according to some example embodiments. Specifically, FIG. 7 illustrates a portion corresponding to FIG. 6A. The cross-section taken along line A3-A3′ of FIG. 7 may be substantially the same as the cross-section of FIG. 6B. In FIG. 7, the same reference numerals as those in FIGS. 2A to 5D, 6A, and 6B denote the same members, and descriptions thereof are not repeated.

Referring to FIG. 7, the printed circuit board 500b may have substantially the same configuration as the printed circuit board 500a described with reference to FIGS. 6A and 6B. However, in the printed circuit board 500b, at least some of the centers of three pairs of conductive vias 542, 544, and 546 and a pair of lower pads 534 may not be arranged on a straight line.

In some embodiments, in a plan view, a first line-side via 542 from among the pair of line-side vias 542, a first intermediate via 546 from among the pair of intermediate vias 546, a first pad-side via 544 from among the pair of pad-side vias 544, and a first lower pad 534 from among the pair of lower pads 534 may be arranged on one side with respect to the center line CX. In some embodiments, in a plan view, a second line-side via 542 from among the pair of line-side vias 542, a second intermediate via 546 from among the pair of intermediate vias 546, a second pad-side via 544 from among the pair of pad-side vias 544, and a second lower pad 534 from among the pair of lower pads 534 may be arranged on the other side opposite to the one side with respect to the center line CX.

In some embodiments, at least some of the center of the first line-side via 542, the center of the first intermediate via 546, the center of the first pad-side via 544, and the center of the first lower pad 534 may not be arranged on a straight line passing through the remaining centers. In some embodiments, at least some of the center of the second line-side via 542, the center of the second intermediate via 546, the center of the second pad-side via 544, and the center of the second lower pad 534 may not be arranged on a straight line passing through the remaining centers.

In some embodiments, the distances of at least some of the three pairs of conductive vias 542, 544, and 546 from the center line CX in the first horizontal direction (the X direction) may be equal to each other. In some embodiments, at least some of the first via pitch VP1, the second via pitch VP2, and the third via pitch VP3 may have the same length.

Referring to FIG. 7, the center of the first line-side via 542 and the center of the first intermediate via 546 may be arranged on the first straight line, and the center of the first pad-side via 544 and the center of the lower pad 534 may not be arranged on the first straight line. In some embodiments, a first separation distance, which is the distance of the first line-side via 542 from the center line CX in the first horizontal direction (the X direction) may be substantially equal to a second separation distance, which is the distance of the first intermediate via 546 from the center line CX in the first horizontal direction (the X direction). A third separation distance, which is the distance of the first pad-side via 544 from the center line CX in the first horizontal direction (the X direction) may be different from the first separation distance. For example, the first via pitch VP1 may be substantially the same as the third via pitch VP3, and the second via pitch VP2 may be greater than the first via pitch VP1.

In some embodiments, the three pairs of conductive vias 542, 544, and 546 may be symmetrically arranged with respect to the center line CX. In some embodiments, in a plan view, the three pairs of conductive vias 542, 544, and 546 may be arranged in a Y-shape.

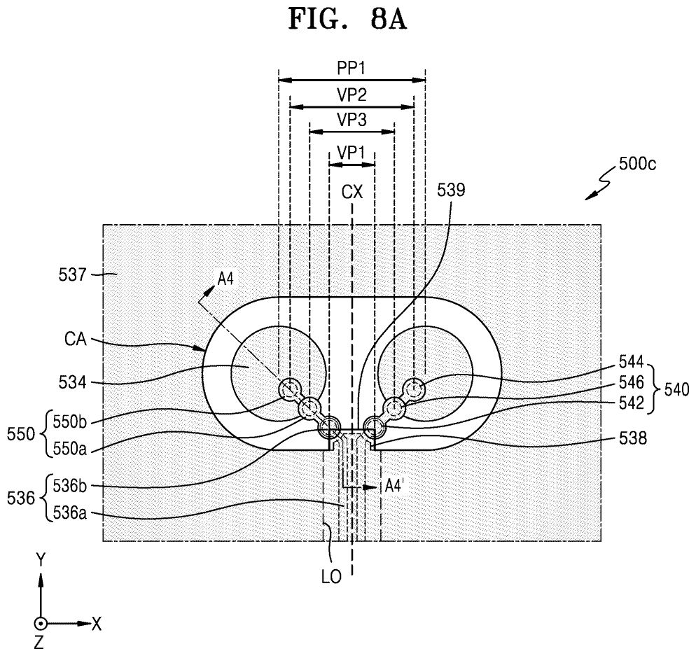

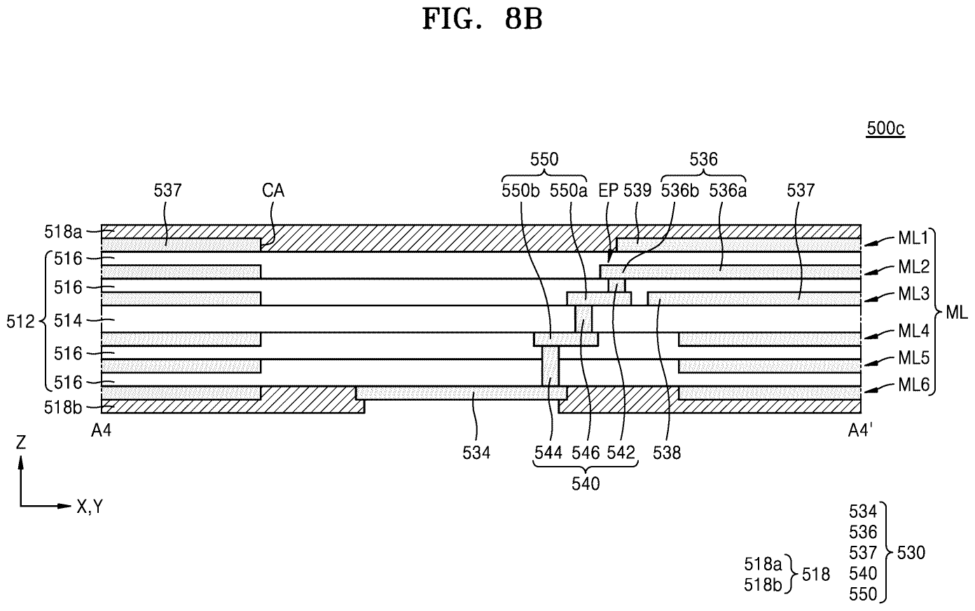

FIG. 8A is a plan view illustrating a printed circuit board 500c according to some example embodiments, and FIG. 8B is a cross-sectional view taken along line A4-A4′ of FIG. 8A. In FIGS. 8A and 8B, the same reference numerals as those in FIGS. 2A to 5D, 6A, and 6B denote the same members, and descriptions thereof are omitted.

Referring to FIGS. 8A and 8B, the printed circuit board 500c may have substantially the same configuration as the printed circuit board 500a described with reference to FIGS. 6A and 6B. However, the printed circuit board 500c includes a second reinforcement structure 539, and some of three pairs of conductive vias 542, 544, and 546 penetrate through two board layers (e.g., two sub-board layers 516) in the vertical direction (the Z direction).

Referring to FIG. 8B, the printed circuit board 500c may include six wiring layers ML1, ML2, . . . , ML5, and ML6. In some embodiments, the second wiring layer ML2 may include a pair of differential signal lines 536, and the sixth wiring layer ML6 may include a pair of lower pads 534. In some embodiments, the first wiring layer ML1 may include the second reinforcement structure 539, and the third wiring layer ML3 may include a first reinforcement structure 538.

In some embodiments, the pair of line-side vias 542 may penetrate through a sub-board layer 516 between the second wiring layer ML2 and the third wiring layer ML3 and may be in contact with a pair of upper via pads 550a of the third wiring layer ML3. The second reinforcement structure 539 and the first reinforcement structure 538 may be respectively included in the first wiring layer ML1 and the third wiring layer ML3, which are the wiring layers ML closest to the pair of differential signal lines 536, and may at least partially vertically overlap an entry portion EP of the pair of differential signal lines 536.

In some embodiments, the first reinforcement structure 538 may be spaced apart from the pair of line-side vias 542, and a chamfered portion (see, e.g., chamfered portion CP of FIGS. 6A and 4) of the first reinforcement structure 538 may face a sidewall of each of the pair of line-side vias 542. For example, the chamfered portion CP may have a profile corresponding to the sidewall of each of the pair of line-side vias 542.

In some embodiments, the pair of intermediate vias 546 may penetrate through a core board layer 514 between the third wiring layer ML3 and the fourth wiring layer ML4 and may be in contact with the pair of lower via pads 550b. In some embodiments, the pair of pad-side vias 544 may penetrate through the sub-board layer 516 between the fourth wiring layer ML4 and the fifth wiring layer ML5 and the sub-board layer 516 between the fifth wiring layer ML5 and the sixth wiring layer ML6 and may be in contact with the pair of lower pads 534.

Although FIG. 8B illustrates that the pair of pad-side vias 544 penetrate through the two board layers, the inventive concept is not limited thereto. In some embodiments, the pair of intermediate vias 546 or the pair of line-side vias 542 may penetrate through the two board layers. In some embodiments, the pair of intermediate vias 546 may be omitted and the pair of pad-side vias 544 may penetrate through three or more board layers. In some embodiments, the printed circuit board 500c may include more than six wiring layers ML, and two or more pairs of conductive vias from among the three pairs of conductive vias 542, 544, and 546 may each penetrate through two or more board layers.

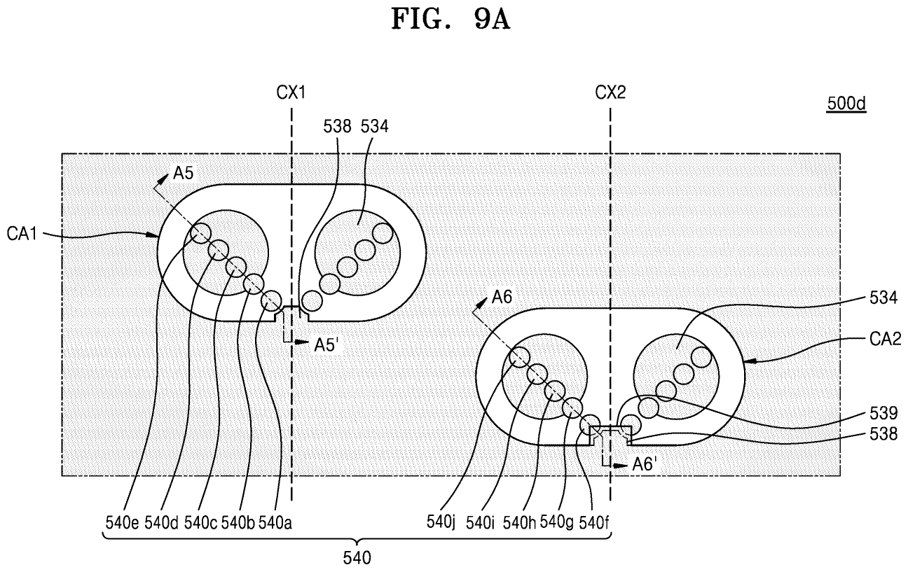

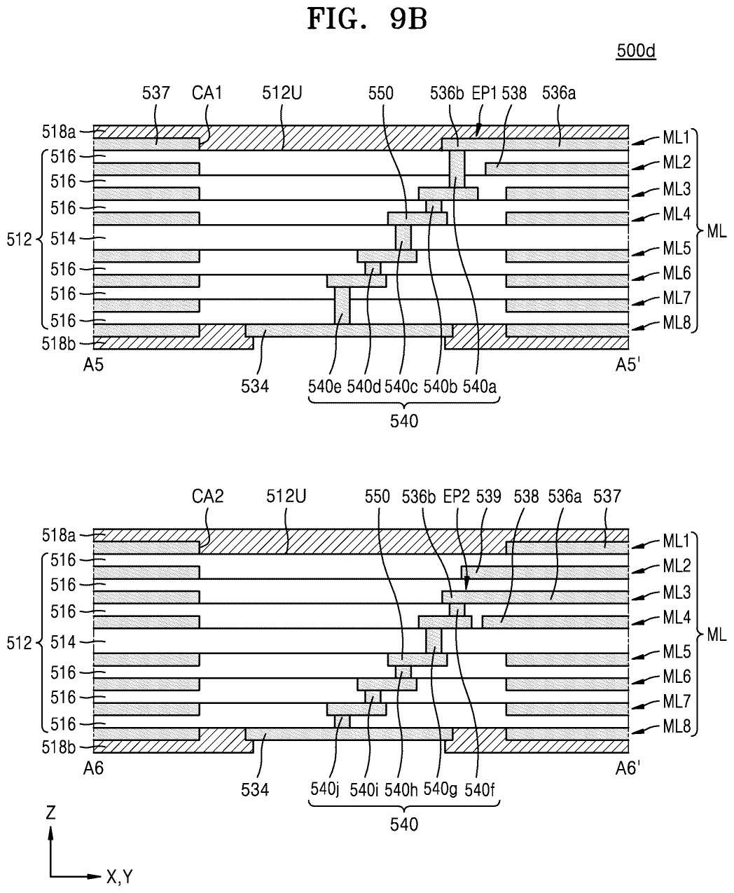

FIG. 9A is a plan view illustrating a printed circuit board 500d according to some example embodiments, and FIG. 9B is a cross-sectional view taken along lines A5-A5′ and A6-A6′ of FIG. 9A. In FIGS. 9A and 9B, the same reference numerals as those in FIGS. 2A to 8B denote the same members, and descriptions thereof are omitted.

Referring to FIGS. 9A and 9B, the plurality of wiring layers ML of the printed circuit board 500d may include a common potential plate 537 having a plurality of cut areas CA1 and CA2. In some embodiments, the printed circuit board 500d may include a plurality of pairs of differential signal lines 536 included in different wiring layers ML. For example, a first differential signal line 536 from among the pairs of differential signal lines 536 may be included in the first wiring layer ML1 and may include a first entry portion EP1 extending to the first cut area CA1. For example, a second differential signal line 536 from among the pairs of differential signal lines 536 may be included in the third wiring layer ML3 and may include a second entry portion EP2 extending to the second cut area CA2.

In some embodiments, the first cut area CA1 and the second cut area CA2 may be spaced apart from each other in the horizontal direction (the X direction and/or the Y direction).

In some embodiments, the first differential signal line 536 may be included in the uppermost wiring layer ML1, and the first entry portion EP1 may partially vertically overlap a first lower reinforcement structure 538 of the second wiring layer ML2.

In some embodiments, the second differential signal line 536 may be included in the third wiring layer ML3, and the second entry portion EP2 may partially vertically overlap a second lower reinforcement structure 538 of the fourth wiring layer ML4. In some embodiments, the second entry portion EP2 may at least partially vertically overlap the upper reinforcement structure 539 in the second cut area CA2 of the second wiring layer ML2.

In some embodiments, a plurality of pairs of conductive vias 540a, 540b, 540c, 540d, and 540e may be arranged in the first cut area CA1 to constitute a first wiring path (see, e.g., wiring path 535 of FIG. 1). For example, a pair of via pads 550 may be arranged between each pair of conductive vias 540a, 540b, 540c, 540d, and 540e. The lengths of some of the pairs of conductive vias 540a, 540b, 540c, 540d, and 540e in the vertical direction (the Z direction) may be different from each other. In FIG. 8A, the pairs of via pads 550 are omitted for convenience.

In some embodiments, the pairs of conductive vias 540a, 540b, 540c, 540d, and 540e may be symmetrically arranged with respect to a first virtual center line CX1 extending in the second horizontal direction (the Y direction). For example, the pairs of conductive vias 540a, 540b, 540c, 540d, and 540e may be spaced apart from each other in the first horizontal direction (the X direction).

In some embodiments, the pairs of conductive vias 540a, 540b, 540c, 540d, and 540e may be arranged so that the distance from the first center line CX1 increases as the distance from the first entry portion EP1 increases. In some embodiments, in a plan view, the pairs of conductive vias 540a, 540b, 540c, 540d, and 540e may be arranged in a V-shape.

In some embodiments, a plurality of pairs of conductive vias 540f, 540g, 540h, 540i, and 540j may be arranged in the second cut area CA2 to constitute a second wiring path 535. For example, one via pad 550 may be arranged between each pair of conductive vias 540f, 540g, 540h, 540i, and 540j.

In some embodiments, the pairs of conductive vias 540f, 540g, 540h, 540i, and 540j may be symmetrically arranged with respect to a second virtual center line CX2 extending in the second horizontal direction (the Y direction). For example, the pairs of conductive vias 540f, 540g, 540h, 540i, and 540j may be spaced apart from each other in the first horizontal direction (the X direction).

In some embodiments, the pairs of conductive vias 540f, 540g, 540h, 540i, and 540j may be arranged so that the distance from the second center line CX2 increases as the distance from the second entry portion EP2 increases. In some embodiments, in a plan view, the pairs of conductive vias 540f, 540g, 540h, 540i, and 540j may be arranged in a V-shape. In some other embodiments, in a plan view, the pairs of conductive vias 540f, 540g, 540h, 540i, and 540j may be arranged in a Y-shape, as in the printed circuit board 500b described with reference to FIG. 7.

Although FIGS. 9A and 9B illustrate that, in a plan view, the same number of conductive vias 540 are arranged in the first cut area CA1 and the second cut area CA2, the inventive concept is not limited thereto. For example, the number of pairs of conductive vias 540 arranged in the first cut area CA1 may be different from the number of pairs of conductive vias 540 arranged in the second cut area CA2.

Although the printed circuit boards 500, 500a, and 500b described with reference to FIGS. 2A to 7 are illustrated as including four wiring layers ML, the printed circuit board 500c described with reference to FIGS. 8A and 8B are illustrated as including six wiring layers ML, and the printed circuit board 500d described with reference to FIGS. 9A and 9B are illustrated as including eight wiring layers ML, the inventive concept is not limited to the above-described embodiments.

Specific embodiments are presented for helping understanding of the inventive concept, but these are merely illustrative and the inventive concept is not limited to the following embodiments.

### Embodiments 1 to 7

Table 1 below shows the arrangement relationship between the pair of differential signal lines 536 and the plurality of pairs of conductive vias 540 of the printed circuit board having various numbers of wirign layers ML according to embodiments.

TABLE 1

| | Embodiment 1 | Embodiment 2 | Embodiment 3 | Embodiment 4 | Embodiment 5 | Embodiment 6 | Embodiment 7 |
|---|---|---|---|---|---|---|---|
| Position of | ML1 | ML1 | ML1 | ML2 | ML1 | ML2 | ML1 |
| differential | | | | | | | |
| signal line | | | | | | | |
| Number of | 4 | 6 | 8 | 8 | 10 | 10 | 12 |
| wiring layers | | | | | | | |
| ML1-ML2 | Va | Va | Va | — | Va | — | Va |
| ML2-ML3 | Vb | Va | Va | Va | Va | Va | Va |
| ML3-ML4 | Vc | Vb | Vb | Vb | Vb | Vb | Vb |
| ML4-ML5 | | Vc | Va | Vc | Vb | Vb | Vb |
| ML5-ML6 | | Vc | Vb | Vb | Va | Vc | Va |
| ML6-ML7 | | | Vc | Vc | Vb | Vb | Vb |
| ML7-ML8 | | | Vc | Vc | Vb | Vb | Va |
| ML8-ML9 | | | | | Vc | Vc | Vb |
| ML9-ML10 | | | | | Vc | Vc | Vb |
| ML10-ML11 | | | | | | | Vc |
| ML11-ML12 | | | | | | | Vc |
| Position of | ML2 | ML2 | ML2 | ML3 | ML2 | ML3 | ML2 |
| first | | | | | | | |
| reinforcement | | | | | | | |
| structure | | | | | | | |
| Position of | — | — | — | ML1 | — | ML1 | — |
| second | | | | | | | |
| reinforcement | | | | | | | |
| structure | | | | | | | |

In Table 1, “Va” represents the pair of line-side vias 542, “Vb” represents the pair of intermediate vias 546, and “Vc” represents the pair of pad-side vias 544. In Table 1, “MLa-MLb” means that the pair of conductive vias 540 extend between an a^{th} wiring layer MLa and a b^{th} wiring layer MLb. The arrangement relationship between the line-side via 542, the pad-side via 544, and the intermediate via 546 is the same as described with reference to FIGS. 6A and 6B. In the embodiments of Table 1, the number of wiring layers and the number of conductive vias are illustrative, and the inventive concept is not limited thereto.

While the inventive concept has been particularly shown and described with reference to embodiments thereof, it will be understood that various changes in form and details may be made therein without departing from the spirit and scope of the following claims.

What is claimed is:

1. A printed circuit board comprising:
a plurality of wiring layers spaced apart from each other in a vertical direction, the plurality of wiring layers each comprising a common potential plate having a cut area; and
a plurality of conductive vias extending between the plurality of wiring layers,
wherein the plurality of wiring layers comprise:
a first wiring layer spaced apart from the common potential plate, the first wiring layer comprising a pair of differential signal lines each comprising an entry portion extending into the cut area;
a second wiring layer comprising a first reinforcement structure extending from the common potential plate and vertically overlapping a portion of the entry portion, and a pair of via pads spaced apart from the entry portion within the cut area; and
a third wiring layer spaced apart from the first wiring layer in the vertical direction with the second wiring layer therebetween, the third wiring layer comprising a pair of lower pads in the cut area, and
wherein the plurality of conductive vias comprise:
a pair of line-side vias in contact with the pair of differential signal lines and the pair of via pads; and
a pair of pad-side vias in contact with the pair of via pads and the pair of lower pads.

2. The printed circuit board of claim 1, wherein, in a plan view, the pair of differential signal lines are spaced apart from the pair of lower pads.

3. The printed circuit board of claim 1, wherein the first reinforcement structure has a chamfered portion recessed along a sidewall of each of the pair of via pads.

4. The printed circuit board of claim 1,
wherein the pair of differential signal lines each comprise a signal line partially overlapping the first reinforcement structure in the vertical direction and a signal pad in contact with each of the pair of line-side vias,
wherein the pair of differential signal lines are spaced apart from each other in a first horizontal direction, and
wherein a first length, which is a width of the first reinforcement structure in the first horizontal direction, is greater than a second length, the second length being a sum of a distance of the pair of differential signal lines in the first horizontal direction and twice a width of the signal line in the first horizontal direction.

5. The printed circuit board of claim 1, wherein the pair of line-side vias and the pair of pad-side vias do not overlap each other in the vertical direction.

6. The printed circuit board of claim 1,
wherein the pair of line-side vias are spaced apart from each other by a first distance in a first horizontal direction,
wherein the pair of pad-side vias are spaced apart from each other by a second distance in the first horizontal direction, and
wherein the second distance is greater than the first distance.

7. The printed circuit board of claim 1, wherein, in a plan view, the pair of pad-side vias and the pair of line-side vias are arranged in a V-shape.

8. The printed circuit board of claim 1,
wherein the plurality of wiring layers further comprise a fourth wiring layer spaced apart from the second wiring layer in a vertical direction with the first wiring layer therebetween, and
wherein the fourth wiring layer comprises a second reinforcement structure at least partially overlapping the entry portion in the vertical direction.

9. The printed circuit board of claim 8, wherein the second reinforcement structure overlaps the first reinforcement structure in the vertical direction and at least partially overlaps the pair of line-side vias in the vertical direction.

10. The printed circuit board of claim 8, wherein the second reinforcement structure has a larger planar area than the first reinforcement structure.

11. A printed circuit board comprising:
a base board; and
a wiring structure arranged on a top surface and a bottom surface of the base board and inside the base board,
wherein the wiring structure comprises:
a plurality of common potential plates spaced apart from each other in a vertical direction, the plurality of common potential plates each having a cut area;
a pair of differential signal lines spaced apart from a first common potential plate selected from among the plurality of common potential plates, the pair of differential signal lines each comprising an entry portion arranged in the cut area; and
a first reinforcement structure extending from a second common potential plate selected from among the plurality of common potential plates and overlapping a portion of the entry portion in the vertical direction.

12. The printed circuit board of claim 11, further comprising:
a pair of lower pads arranged in the cut area on the bottom surface of the base board; and
a pair of via pads arranged inside the cut area and arranged at a vertical level lower than a vertical level of the first common potential plate,
wherein each of the pair of via pads overlaps in the vertical direction a corresponding lower pad from among the pair of lower pads and a corresponding differential signal line from among the pair of differential signal lines.

13. The printed circuit board of claim 12, wherein, in a plan view, the pair of via pads are spaced apart from the first reinforcement structure.

14. The printed circuit board of claim 12,
wherein the pair of via pads are spaced apart from each other in a first horizontal direction, and
wherein a distance between the pair of via pads in the first horizontal direction increases as a distance from the entry portion increases.

15. The printed circuit board of claim 12, further comprising:
a pair of line-side vias extending between the pair of differential signal lines and the pair of via pads; and
a pair of pad-side vias extending between the pair of lower pads and the pair of via pads,
wherein, in a plan view, a center of one selected from among the pair of lower pads, a center of one selected from among the pair of line-side vias, and a center of one selected from among the pair of pad-side vias are arranged on a first straight line.

16. The printed circuit board of claim 12, further comprising:
a pair of line-side vias extending between the pair of differential signal lines and the pair of via pads; and
a pair of pad-side vias extending between the pair of lower pads and the pair of via pads,
wherein the pair of line-side vias and the pair of pad-side vias do not overlap each other in the vertical direction.

17. The printed circuit board of claim 12, further comprising:
a pair of line-side vias extending between the pair of differential signal lines and the pair of via pads; and
a pair of pad-side vias extending between the pair of lower pads and the pair of via pads,
wherein, in a plan view, the pair of line-side vias and the pair of pad-side vias are arranged in a V-shape.

18. The printed circuit board of claim 11,
wherein the plurality of common potential plates comprise a third common potential plate selected from among the plurality of common potential plates and spaced apart from the second common potential plate in the vertical direction with the first common potential plate therebetween, and
wherein the printed circuit board further comprises a second reinforcement structure extending from the third common potential plate and vertically overlapping at least a portion of the entry portion.

19. A printed circuit board comprising:
a base board; and
a wiring structure arranged on a top surface and a bottom surface of the base board and inside the base board,
wherein the wiring structure comprises:
a plurality of common potential plates spaced apart from each other in a vertical direction, the plurality of common potential plates each having a cut area;
a pair of differential signal lines spaced apart from a first common potential plate selected from among the plurality of common potential plates, the pair of differential signal lines each comprising an entry portion arranged in the cut area;
a first reinforcement structure extending from a second common potential plate selected from among the plurality of common potential plates and overlapping a portion of the entry portion in the vertical direction;
a second reinforcement structure selected from among the plurality of common potential plates, extending from a third common potential plate spaced apart from the second common potential plate in the vertical direction with the first common potential plate therebetween, and overlapping at least a portion of the entry portion in the vertical direction;
a pair of lower pads arranged in the cut area on a bottom surface of the base board;
a pair of via pads arranged inside the cut area and arranged at a vertical level lower than a vertical level of the first common potential plate;
a pair of line-side vias extending between the pair of differential signal lines and the pair of via pads; and
a pair of pad-side vias extending between the pair of lower pads and the pair of via pads.

20. The printed circuit board of claim 19,
wherein, in a plan view, the pair of differential signal lines are spaced apart from the pair of lower pads, and
wherein in the plan view, the pair of line-side vias and the pair of pad-side vias are arranged in a V-shape.
